(19) United States
(12) Patent Application Publication
(10) Pub. No.: US 2025/0364363 A1
(43) Pub. Date: Nov. 27, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shih-Ping CHANG, Taichung City (TW); Liang-Pin CHEN, Taichung City (TW)

(21) Appl. No.: 18/768,732

(22) Filed: Jul. 10, 2024

(30) Foreign Application Priority Data
May 22, 2024 (TW) 113118953

(51) Int. Cl. H01L 23/46; H01L 23/00; H01L 23/31; H01L 23/36; H01L 23/49; H01L 23/498; H01L 23/538; H01L 25/00; H01L 25/10; H10B 80/00; H10N 10/10

(52) U.S. Cl. CPC H01L 23/46; H01L 23/3107; H01L 23/36; H01L 23/49; H01L 25/105; H01L 25/50; H01L 23/49816; H01L 23/5383; H01L 24/16; H01L 24/24; H01L 24/25; H01L 24/32; H01L 24/73; H01L 2224/16227; H01L 2224/24145; H01L 2224/2518; H01L 2224/32225; H01L 2224/73267; H01L 2225/1094; H10B 80/00; H10N 10/10

(57) ABSTRACT

An electronic package and a manufacturing method thereof are provided, in which a thermoelectric circuit structure and a thermal conductive structure are provided on a wiring structure connected to electronic components. The thermal conductive structure includes a thermal conductive board and thermal conductive pillars, the thermal conductive board and the thermal conductive pillars form interconnected hollow chambers for injecting a working fluid, and one end of each of the thermal conductive pillars is connected to the thermal conductive board, and the other end is connected to the thermoelectric circuit structure to generate a voltage via the temperature difference to drive the working fluid inside the thermal conductive structure to flow, thereby achieving the heat dissipation effect of the electronic package.

### CROSS-REFERENCE TO RELATED APPLICATIONS

The present application is based upon and claims the right of priority to TW Patent Application No. 113118953, filed May 22, 2024, the disclosure of which is hereby incorporated by reference herein in its entirety for all purposes.

### BACKGROUND

### 1. Technical Field

The present disclosure relates to a semiconductor packaging technology, and more particularly, to an electronic package and a manufacturing method thereof.

### 2. Description of Related Art

The application of high-performance computing (HPC) technology in today's life has become increasingly widespread and important, such as in the development of cancer drugs or the automatic sensing detection calculation of self-driving cars. The package structures used in electronic components that are applied to equipment in these fields are mostly fan-out package (FO PKG) structures, for example, structures such as fan-out multi-chip module (FOMCM) and fan-out embedded bridge (FOEB) die, and these structures have strong demands for multi-chip, multiple redistribution layers, large fan-out size, and high heat dissipation design.

As shown in FIG. 1, in order to produce the above-mentioned fan-out package structure for the industry, a bridge chip 11 is embedded in a package structure 1, then a redistribution layer (RDL) 12 is formed above the bridge chip 11, and then a functional chip 13 such as a graphics processing unit (GPU) and a high bandwidth memory (HBM) 14 are placed side by side or stacked on the redistribution layer 12. In this way, the functional chip 13 and the high bandwidth memory 14 can communicate via the bridge chip 11 to meet signal transmission requirements.

However, the aforementioned package structure 1 requires higher density electronic components and electronic circuits as more and more functional requirements are needed for electronic products. Therefore, the package structure 1 will generate a larger amount of heat energy during operation. Accordingly, if the heat cannot be effectively dissipated, damage to the package structure 1 and product reliability problems will occur.

Therefore, how to overcome the above-mentioned drawbacks of the prior art has become an urgent issue to be solved.

### SUMMARY

In view of the various deficiencies of the prior art, the present disclosure provides an electronic package, which comprises: a wiring structure; a thermoelectric circuit structure disposed on the wiring structure; electronic components disposed on and electrically connected to the wiring structure; and a thermal conductive structure erected on the wiring structure and covering the electronic components, wherein the thermal conductive structure includes a thermal conductive board and thermal conductive pillars, and the thermal conductive board and the thermal conductive pillars form interconnected hollow chambers for injecting a working fluid, wherein one end of each of the thermal conductive pillars is connected to the thermal conductive board, and the other end is connected to the thermoelectric circuit structure to generate a voltage via a temperature difference to drive the working fluid to flow.

The present disclosure further comprises a method of manufacturing an electronic package, the method comprises: disposing electronic components on a wiring structure, wherein the electronic components are electrically connected to the wiring structure; disposing a thermoelectric circuit structure on the wiring structure; and erecting a thermal conductive structure on the wiring structure to cover the electronic components, wherein the thermal conductive structure includes a thermal conductive board and thermal conductive pillars, and the thermal conductive board and the thermal conductive pillars form interconnected hollow chambers for injecting a working fluid, wherein one end of each of the thermal conductive pillars is connected to the thermal conductive board, and the other end is connected to the thermoelectric circuit structure to generate a voltage via a temperature difference to drive the working fluid to flow.

In the aforementioned electronic package and method, the electronic components include a first electronic component, second electronic components and a third electronic component, wherein the first electronic component has a first active surface and is disposed in a first encapsulation layer, each of the second electronic components has a second active surface and is disposed in a second encapsulation layer above the first encapsulation layer, the third electronic component has a third active surface and is disposed in a third encapsulation layer above the second encapsulation layer, and the third active surface is opposite to and electrically connected to the first active surface and the second active surface, respectively.

In the aforementioned electronic package and method, the first active surface has a plurality of first connection pads thereon, and at least some of the plurality of first connection pads are directly electrically connected to the third active surface.

In the aforementioned electronic package and method, the present disclosure further comprises a circuit structure, wherein the circuit structure is disposed between the second electronic components and the third electronic component, and the circuit structure has a first surface, a second surface opposing the first surface, and a circuit layer, wherein the third active surface of the third electronic component is electrically connected to the second active surface of each of the second electronic components via the circuit layer.

In the aforementioned electronic package and method, the third electronic component is disposed on the second surface of the circuit structure via the third active surface.

In the aforementioned electronic package and method, each of the second electronic components is connected to the first surface of the circuit structure via the second active surface.

In the aforementioned electronic package and method, the third electronic component is a graphics processor or a central processing unit, each of the second electronic components is a memory chip or a memory module, and the first electronic component is an auxiliary electronic component.

In the aforementioned electronic package and method, the present disclosure further comprises a wiring structure disposed under the first electronic component, wherein the wiring structure is electrically connected to the first electronic component.

In the aforementioned electronic package and method, the first electronic component is adhered onto the wiring structure via a die attach film.

As can be seen from above, in the electronic package and manufacturing method thereof of the present disclosure, a thermoelectric circuit structure and a thermal conductive structure are disposed on the wiring structure, wherein the thermal conductive structure includes a thermal conductive board and thermal conductive pillars, the thermal conductive board and the thermal conductive pillars form interconnected hollow chambers for injecting working fluid, wherein one end of each of the thermal conductive pillars is connected to the thermal conductive board, and the other end is connected to the thermoelectric circuit structure to generate a voltage via the temperature difference, thereby driving the working fluid inside the thermal conductive structure to flow to generate a water circulation effect, thereby achieving the heat dissipation effect of the electronic package. In addition, in the present disclosure, the first electronic component (or the auxiliary electronic component) located in the first encapsulation layer at the bottom of the electronic package and the second electronic components located in the second encapsulation layer in the middle of the electronic package can be directly electrically connected to the third electronic component located in the third encapsulation layer on the upper part of the electronic package to accelerate the signal transmission speed in the package. And because the third electronic component can be directly electrically connected to the first electronic component and/or the second electronic components without the need to provide a bridging component therein as in the conventional package structure, the auxiliary electronic component can be provided to assist in the work processing within the package, thereby further improving the overall performance of the electronic package.

### BRIEF DESCRIPTION OF THE DRAWINGS

FIG. 1 is a schematic cross-sectional view of a conventional package structure.

FIG. 2A to FIG. 2F are schematic cross-sectional views illustrating a manufacturing method of an electronic package according to an embodiment of the present disclosure.

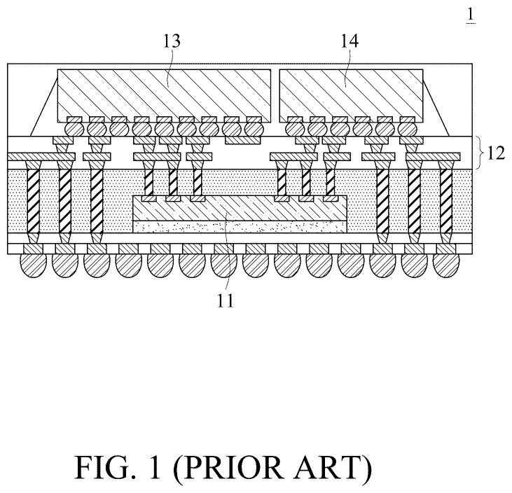

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

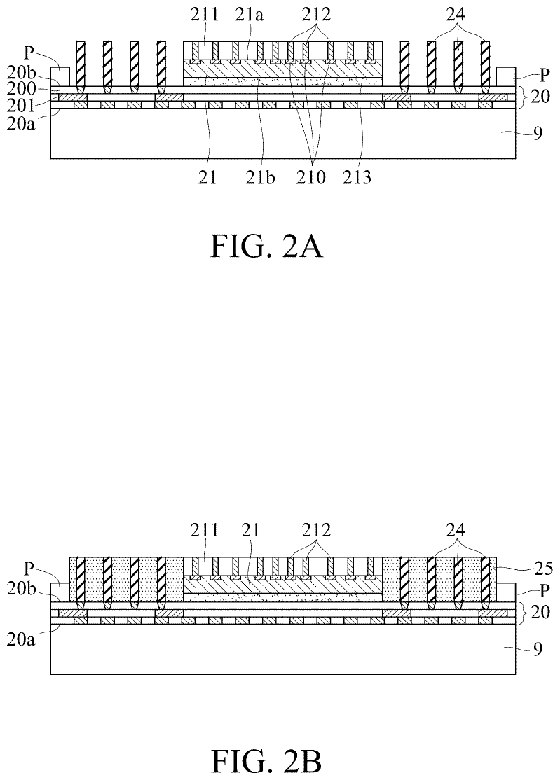

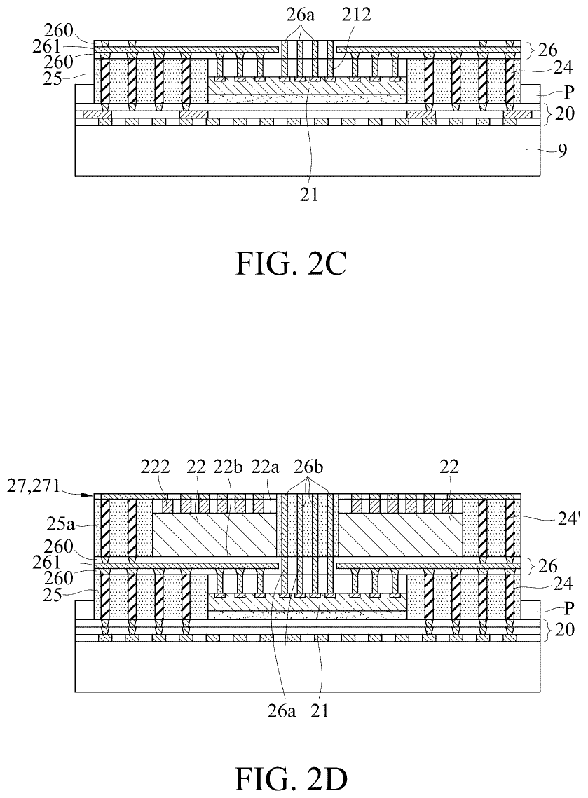

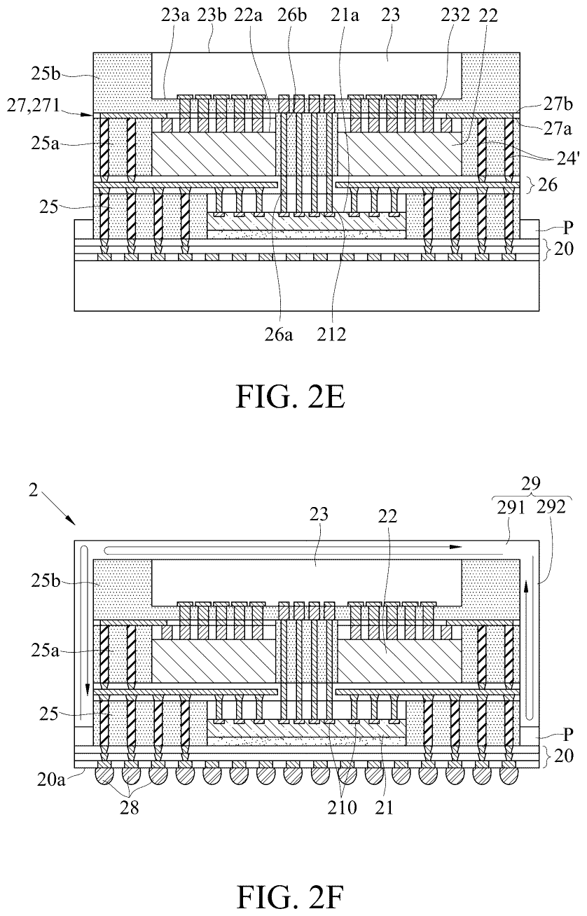

FIG. 2A to FIG. 2F are schematic cross-sectional views illustrating a manufacturing method of an electronic package 2 according to an embodiment of the present disclosure.

As shown in FIG. 2A, a wiring structure 20 is formed on a carrier board 9, and at least one first electronic component 21 is disposed on the wiring structure 20.

The carrier board 9 is, for example, a board made of semiconductor material or glass material.

The wiring structure 20 is defined with a first side 20a and a second side 20b opposing the first side 20a, and the wiring structure 20 has a dielectric layer 200 and a first circuit layer 201 formed on the dielectric layer 200, such as in the form of a redistribution layer (RDL). The first side 20a of the wiring structure 20 is bonded onto the carrier board 9, and the first electronic component 21 is disposed on the second side 20b of the wiring structure 20. In addition, a plurality of conductive structures 24 electrically connected to the first circuit layer 201 are formed on the second side 20b of the wiring structure 20, and a thermoelectric circuit structure P is disposed on the second side 20b of the wiring structure 20.

In one embodiment, the material for forming the first circuit layer 201 is such as copper, and the dielectric layer 200 is made of dielectric material such as polybenzoxazole (PBO), polyimide (PI), prepreg (PP), or the like.

The first electronic component 21 is an active component, a passive component, or a combination of the active component and the passive component. The active component is such as a semiconductor chip, and the passive component is such as a resistor, a capacitor, or an inductor. In one embodiment, the first electronic component 21 is a semiconductor chip. The first electronic component 21 has a first active surface 21a and a first inactive surface 21b opposing the first active surface 21a, wherein the first inactive surface 21b of the first electronic component 21 is adhered onto the second side 20b of the wiring structure 20 via a glue or a die attach film (DAF) 213, and the first active surface 21a has a plurality of first connection pads 210, so that a plurality of first conductors 212 are formed on the plurality of first connection pads 210, and an insulating layer 211 is formed on the first active surface 21a, so that the insulating layer 211 covers the first connection pads 210 and the first conductors 212. Alternatively, the first conductors 212 can also be exposed from the insulating layer 211.

In one embodiment, the first conductors 212 are, for example, copper pillars, but the first conductors 212 may also be pillar-shaped bodies made of metal materials, such as solder bumps.

The conductive structures 24 are disposed on the second side 20b of the wiring structure 20 and are electrically connected to the first circuit layer 201. In one embodiment, each of the conductive structures 24 is a pillar-shaped body and is made of metal material such as copper or made of solder material.

In addition, the thermoelectric circuit structure P is made of thermoelectric material and is disposed at the periphery of the second side 20b of the wiring structure 20.

As shown in FIG. 2B, a first encapsulation layer 25 is formed on the second side 20b of the wiring structure 20, so that the first encapsulation layer 25 covers the first electronic component 21 and the conductive structures 24. Then, via a leveling process, an upper surface of the first encapsulation layer 25 is flush with an upper surface of the insulating layer 211, end surfaces of the conductive structures 24 and end surfaces of the first conductors 212, so that the upper surface of the insulating layer 211, the end surfaces of the conductive structures 24 and the end surfaces of the first conductors 212 are exposed from the first encapsulation layer 25.

In addition, the thermoelectric circuit structure P is also exposed from the first encapsulation layer 25.

In one embodiment, the first encapsulation layer 25 is made of insulating material such as polyimide (PI), dry film, epoxy resin, or molding compound, but the present disclosure is not limited to as such. Furthermore, the first encapsulation layer 25 can be formed on the second side 20b of the wiring structure 20 by lamination or molding.

In addition, the leveling process employs grinding to remove part of the material of the conductive structures 24, part of the material of the insulating layer 211 (if required, part of the material of the first conductors 212 can be removed at the same time), and part of the material of the first encapsulation layer 25.

It should be understood that if the first conductors 212 have been exposed from the insulating layer 211, removing part of the material of the insulating layer 211 can expose the first conductors 212 from the first encapsulation layer 25 (according to requirements, part of the material of the insulating layer 211 and part of the material of the first conductors 212 can also be removed at the same time, so that the first conductors 212 are exposed from the first encapsulation layer 25).

As shown in FIG. 2C, a middle circuit structure 26 is formed on the first encapsulation layer 25, and the middle circuit structure 26 is electrically connected to the wiring structure 20 via the plurality of conductive structures 24. In addition, a plurality of first conductive pillars 26a are formed in the middle circuit structure 26, and each of the first conductive pillars 26a is bonded and electrically connected to each of the corresponding first conductors 212. Each of the first conductive pillars 26a may be made of the same material as each of the first conductors 212, such as a copper pillar.

In an embodiment, the middle circuit structure 26 includes a middle dielectric layer 260 and a middle circuit layer 261 (such as an RDL), and the middle circuit layer 261 is electrically connected to the underlying wiring structure 20 via the plurality of conductive structures 24. Furthermore, the middle circuit layer 261 is made of copper, and the middle dielectric layer 260 is made of dielectric material such as polybenzoxazole (PBO), polyimide (PI), prepreg (PP), or the like.

Next, as shown in FIG. 2D, at least one second electronic component 22 is provided. In one embodiment, two second electronic components 22 are taken as an example. Each of the second electronic components 22 has a second active surface 22a and a second inactive surface 22b opposing the second active surface 22a, and the second inactive surface 22b of each of the second electronic components 22 is disposed above the middle circuit structure 26. Conductive structures 24′ connected to the middle circuit structure 26 may be formed around the second electronic components 22.

The second electronic components 22 are disposed above the first encapsulation layer 25 in such a manner that the second active surface 22a of each of the second electronic components 22 faces upward, and then the second electronic components 22 and the conductive structures 24′ are covered with a second encapsulation layer 25a made of encapsulation material. Next, a circuit structure 27 is formed on the second encapsulation layer 25a.

The conductive structures 24′ are disposed between the middle circuit structure 26 and the circuit structure 27 and are electrically connected to the middle circuit layer 261 and the circuit structure 27, wherein each of the conductive structures 24′ is a pillar-shaped body and is made of metal material such as copper or made of solder material.

The second encapsulation layer 25a is made of insulating material such as polyimide (PI), dry film, epoxy resin, or molding compound, but the present disclosure is not limited to as such. For example, the second encapsulation layer 25a can be formed on the middle circuit structure 26 by lamination or molding. It should be understood that the materials of the second encapsulation layer 25a and the first encapsulation layer 25 may be the same or different.

Each of the second electronic components 22 may be an active component, a passive component, or a combination of the active component and the passive component. The active component is, for example, a dynamic random access memory (DRAM). The passive component is, for example, a resistor, a capacitor, or an inductor. In one embodiment, the two second electronic components 22 are high bandwidth memory (HBM) chips or modules.

The second active surface 22a of each of the second electronic components 22 has a plurality of electrode pads (not shown), and these electrode pads are electrically connected to a circuit layer 271 of the circuit structure 27 (e.g., a redistribution layer) via a plurality of second conductors 222 such as solder bumps, copper bumps, or others. In addition, a plurality of second conductive pillars 26b are formed in the second encapsulation layer 25a, wherein each of the second conductive pillars 26b is correspondingly bonded and electrically connected to each of the first conductive pillars 26a. The second conductive pillars 26b can be made of the same material as the first conductive pillars 26a, such as copper pillars.

Furthermore, the two second electronic components 22 can be electrically connected to the first electronic component 21 via the circuit structure 27, the middle circuit structure 26 and the conductive structures 24′.

As shown in FIG. 2E, at least one third electronic component 23 is provided. The third electronic component 23 has a third active surface 23a, and the third active surface 23a of the third electronic component 23 is disposed on the circuit structure 27 via a plurality of third conductors 232 and faces the first electronic component 21 and the second electronic components 22, wherein the third active surface 23a is opposite to and electrically connected to the first active surface 21a and the second active surface 22a respectively. The third active surface 23a is directly electrically connected to the first active surface 21a via the third conductors 232, the second conductive pillars 26b, the first conductive pillars 26a and the first conductors 212. In this way, the third electronic component 23 and the first electronic component 21 can directly transmit signals without going through other components such as bridge chips or circuit structures. Therefore, the signal transmission speed between the third electronic component 23 and the first electronic component 21 can be accelerated. In addition, the third active surface 23a can be directly electrically connected to the second active surface 22a via the third conductors 232, the circuit structure 27 and the second conductors 222, so as to accelerate the signal transmission speed between the third electronic component 23 and the second electronic components 22.

The third electronic component 23 is, for example, a graphics processor or a central processing unit. In one embodiment, the third electronic component 23 is a graphics processor.

After the third electronic component 23 is disposed, the third electronic component 23 can be covered with a third encapsulation layer 25b made of an encapsulation material. The third encapsulation layer 25b is made of insulating material such as polyimide (PI), dry film, epoxy resin, or molding compound, but the present disclosure is not limited to as such. It can be understood that the material for forming the third encapsulation layer 25b may be the same as or different from the material for forming the second encapsulation layer 25a.

In addition, the third encapsulation layer 25b can be thinned via grinding, for example, so that a third inactive surface 23b of the third electronic component 23 is exposed from the third encapsulation layer 25b.

Furthermore, the thermoelectric circuit structure P is exposed from the first encapsulation layer 25, the second encapsulation layer 25a and the third encapsulation layer 25b.

As shown in FIG. 2F, a thermal conductive structure 29 is disposed on the thermoelectric circuit structure P on the second side 20b of the wiring structure 20, wherein the thermal conductive structure 29 includes a thermal conductive board 291 and thermal conductive pillars 292, the thermal conductive board 291 is disposed on the third electronic component 23 and the third encapsulation layer 25b, and wherein the thermal conductive pillars 292 are disposed on the periphery of the thermal conductive board 291, so that the thermal conductive structure 29 can be erected on the wiring structure 20 via the thermal conductive pillars 292.

In one embodiment, the thermal conductive board 291 and the thermal conductive pillars 292 form hollow chambers that communicate with each other, wherein a working fluid is injected and accommodated therein after the hollow chambers are vacuumized. The working fluid can be water, coolant, methanol, acetone, mercury, etc. In addition, one end of each of the thermal conductive pillars 292 is connected to the thermal conductive board 291, and the other end is connected to the thermoelectric circuit structure P, so that the temperature difference is used to generate a voltage at both ends of the thermoelectric circuit structure P via the Seebeck effect, while the voltage drives the working fluid to generate a water circulation effect to achieve a heat dissipation effect.

In addition, the carrier board 9 is removed to expose the first side 20a of the wiring structure 20, and a ball placement process can be further performed on the first side 20a to form a plurality of solder balls 28 on the bottom surface of the wiring structure 20, so as to produce the electronic package 2 of the present disclosure. Subsequently, the electronic package 2 can be electrically connected to an external device such as a circuit carrier board (not shown) via the plurality of solder balls 28.

In one embodiment, since one side of the electronic package 2 connected to the circuit carrier board (external device) via the wiring structure 20 and the plurality of solder balls 28 is heated to a high temperature, and one side of the third electronic component 23 in the electronic package 2 that is away from the circuit carrier board has a relatively low temperature, the thermal conductive structure 29 covering the periphery of the electronic package 2 can generate a voltage by utilizing the temperature difference between the two sides. Then, the working fluid inside the thermal conductive structure 29 (the thermal conductive board 291 and the thermal conductive pillars 292) is driven to flow to generate a water circulation effect, thereby achieving a heat dissipation effect for the electronic package 2.

The present disclosure discloses an electronic package 2, which comprises: a wiring structure 20; a thermoelectric circuit structure P disposed on the wiring structure 20; electronic components (a first electronic component 21, two second electronic components 22 and a third electronic component 23) disposed on the wiring structure 20 and electrically connected to the wiring structure 20; and a thermal conductive structure 29 disposed on the wiring structure 20 and covering the electronic components, wherein the thermal conductive structure 29 includes a thermal conductive board 291 and thermal conductive pillars 292, the thermal conductive board 291 and the thermal conductive pillars 292 form interconnected hollow chambers for injecting a working fluid, and wherein one end of each of the thermal conductive pillars 292 is connected to the thermal conductive board 291, and the other end is connected to the thermoelectric circuit structure P, so as to generate a voltage via the temperature difference to drive the working fluid to flow.

In one embodiment, the electronic components include a first electronic component 21, two second electronic components 22 and a third electronic component 23, wherein the first electronic component 21 has a first active surface 21a and is disposed in a first encapsulation layer 25; each of the second electronic components 22 has a second active surface 22a and is disposed in a second encapsulation layer 25a above the first encapsulation layer 25; the third electronic component 23 has a third active surface 23a and is disposed in a third encapsulation layer 25b above the second encapsulation layer 25a, wherein the third active surface 23a is opposite to and electrically connected to the first active surface 21a and the second active surface 22a, respectively.

In one embodiment, a plurality of first connection pads 210 are disposed on the first active surface 21a, and at least some of the first connection pads 210 are directly electrically connected to the third active surface 23a. In one embodiment, all of the first connection pads 210 are directly electrically connected to the third active surface 23a.

In one embodiment, a circuit structure 27 is further included. The circuit structure 27 is disposed between the second electronic components 22 and the third electronic component 23, and the circuit structure 27 has a first surface 27a, a second surface 27b opposing the first surface 27a, and a circuit layer 271, wherein the third active surface 23a of the third electronic component 23 is electrically connected to the second active surface 22a of each of the second electronic components 22 via the circuit layer 271.

In one embodiment, the third electronic component 23 is disposed on the second surface 27b of the circuit structure 27 via the third active surface 23a.

In one embodiment, each of the second electronic components 22 is connected to the first surface 27a of the circuit structure 27 via the second active surface 22a.

In one embodiment, the third electronic component 23 is a graphics processor or a central processing unit; each of the second electronic components 22 is a memory chip or a memory module; and the first electronic component 21 is an auxiliary electronic component.

In one embodiment, the first electronic component 21 is adhered onto the wiring structure 20 via a die attach film 213.

In one embodiment, the second encapsulation layer 25a and the first encapsulation layer 25 are formed of the same material; and the third encapsulation layer 25b and the second encapsulation layer 25a are formed of the same material.

To sum up, in the electronic package and manufacturing method thereof of the present disclosure, a thermoelectric circuit structure and a thermal conductive structure are disposed on the wiring structure, wherein the thermal conductive structure includes a thermal conductive board and thermal conductive pillars, the thermal conductive board and the thermal conductive pillars form interconnected hollow chambers for injecting working fluid, wherein one end of each of the thermal conductive pillars is connected to the thermal conductive board, and the other end is connected to the thermoelectric circuit structure to generate a voltage via the temperature difference, thereby driving the working fluid inside the thermal conductive structure to flow to generate a water circulation effect, thereby achieving the heat dissipation effect of the electronic package.

In addition, in the present disclosure, the first electronic component (or the auxiliary electronic component) located in the first encapsulation layer at the bottom of the electronic package and the second electronic components located in the second encapsulation layer in the middle of the electronic package can be directly electrically connected to the third electronic component located in the third encapsulation layer on the upper part of the electronic package to accelerate the signal transmission speed in the package. And because the third electronic component can be directly electrically connected to the first electronic component and/or the second electronic components without the need to provide a bridging component therein as in the conventional package structure, the auxiliary electronic component can be provided to assist in the work processing within the package, thereby further improving the overall performance of the electronic package.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a wiring structure;
a thermoelectric circuit structure disposed on the wiring structure;
electronic components disposed on and electrically connected to the wiring structure; and
a thermal conductive structure erected on the wiring structure and covering the electronic components, wherein the thermal conductive structure includes a thermal conductive board and thermal conductive pillars, and the thermal conductive board and the thermal conductive pillars form interconnected hollow chambers for injecting a working fluid thereinto, wherein one end of each of the thermal conductive pillars is connected to the thermal conductive board, and the other end is connected to the thermoelectric circuit structure to generate a voltage via a temperature difference to drive the working fluid to flow.

2. The electronic package of claim 1, wherein the electronic components include a first electronic component, second electronic components and a third electronic component, wherein the first electronic component has a first active surface and is disposed in a first encapsulation layer, each of the second electronic components has a second active surface and is disposed in a second encapsulation layer above the first encapsulation layer, the third electronic component has a third active surface and is disposed in a third encapsulation layer above the second encapsulation layer, and the third active surface is opposite to and electrically connected to the first active surface and the second active surface, respectively.

3. The electronic package of claim 2, wherein the first active surface has a plurality of first connection pads thereon, and at least a portion of the plurality of first connection pads are directly electrically connected to the third active surface.

4. The electronic package of claim 2, further comprising a circuit structure, wherein the circuit structure is disposed between the second electronic components and the third electronic component, and the circuit structure has a first surface, a second surface opposing the first surface, and a circuit layer, wherein the third active surface of the third electronic component is electrically connected to the second active surface of each of the second electronic components via the circuit layer.

5. The electronic package of claim 4, wherein the third electronic component is disposed on the second surface of the circuit structure via the third active surface.

6. The electronic package of claim 4, wherein each of the second electronic components is connected to the first surface of the circuit structure via the second active surface.

7. The electronic package of claim 2, wherein the third electronic component is a graphics processor or a central processing unit, each of the second electronic components is a memory chip or a memory module, and the first electronic component is an auxiliary electronic component.

8. The electronic package of claim 2, further comprising a wiring structure disposed under the first electronic component, wherein the wiring structure is electrically connected to the first electronic component.

9. The electronic package of claim 8, wherein the first electronic component is adhered onto the wiring structure via a die attach film.

10. A method of manufacturing an electronic package, comprising:
disposing electronic components on a wiring structure, wherein the electronic components are electrically connected to the wiring structure;
disposing a thermoelectric circuit structure on the wiring structure; and
erecting a thermal conductive structure on the wiring structure to cover the electronic components, wherein the thermal conductive structure includes a thermal conductive board and thermal conductive pillars, and the thermal conductive board and the thermal conductive pillars form interconnected hollow chambers for injecting a working fluid thereinto, wherein one end of each of the thermal conductive pillars is connected to the thermal conductive board, and the other end is connected to the thermoelectric circuit structure to generate a voltage via a temperature difference to drive the working fluid to flow.

11. The method of claim 10, wherein the electronic components include a first electronic component, second electronic components and a third electronic component, wherein the first electronic component has a first active surface and is disposed in a first encapsulation layer, each of the second electronic components has a second active surface and is disposed in a second encapsulation layer above the first encapsulation layer, the third electronic component has a third active surface and is disposed in a third encapsulation layer above the second encapsulation layer, and the third active surface is opposite to and electrically connected to the first active surface and the second active surface, respectively.

12. The method of claim 11, wherein the first active surface has a plurality of first connection pads thereon, and at least a portion of the plurality of first connection pads are directly electrically connected to the third active surface.

13. The method of claim 11, further comprising forming a circuit structure, wherein the circuit structure is disposed between the second electronic components and the third electronic component, and the circuit structure has a first surface, a second surface opposing the first surface, and a circuit layer, wherein the third active surface of the third electronic component is electrically connected to the second active surface of each of the second electronic components via the circuit layer.

14. The method of claim 13, wherein the third electronic component is disposed on the second surface of the circuit structure via the third active surface.

15. The method of claim 13, wherein each of the second electronic components is connected to the first surface of the circuit structure via the second active surface.

16. The method of claim 11, wherein the third electronic component is a graphics processor or a central processing unit, each of the second electronic components is a memory chip or a memory module, and the first electronic component is an auxiliary electronic component.

17. The method of claim 11, further comprising disposing a wiring structure under the first electronic component, wherein the wiring structure is electrically connected to the first electronic component.

18. The method of claim 17, wherein the first electronic component is adhered onto the wiring structure via a die attach film.
